(19) United States
(12) Patent Application Publication
(10) Pub. No.: US 2025/0315572 A1
(43) Pub. Date: Oct. 9, 2025

(54) COMPUTER-IMPLEMENTED METHOD FOR CO-SIMULATION USING AN HIL SIMULATOR AND AN SIL SIMULATOR

(71) Applicant: dSPACE GmbH, Paderborn (DE)

(72) Inventors: Rafael YUNIS, Zagreb (HR); Tobias ISENBERG, Paderborn (DE)

(73) Assignee: dSPACE GmbH, Paderborn (DE)

(21) Appl. No.: 19/170,844

(22) Filed: Apr. 4, 2025

(30) Foreign Application Priority Data
Apr. 4, 2024 (DE) 102024109412.5
Apr. 4, 2024 (EP) 24168399

(51) Int. Cl. G06F 30/20

(52) U.S. Cl. CPC G06F 30/20

(57) ABSTRACT

A method for co-simulation, using an HIL simulator that runs in real time and an SIL simulator that runs in a simulation time. A periodic clock pulse is specified with clock instants following one another in a constant clock pulse duration. An SIL simulation step is started, a message is created and sent from the SIL simulator to the HIL simulator when the step is concluded. The message is read out from a queue at a clock instant by the HIL simulator, and then deleted, so that a message that is received first from the queue is read out before a later received message and then deleted in the queue. The steps are repeated the co-simulation ends. The first SIL simulation step is started at a first clock instant, and the directly following SIL simulation step is started at the next possible clock instant in each case.

This nonprovisional application claims priority to German Patent Application No. 10 2024 109 412.5, which was filed in Germany on Apr. 4, 2024, and European Application No. 24168399.4, which was filed on Apr. 4, 2024, and which are both herein incorporated by reference.

### BACKGROUND OF THE INVENTION

### Field of the Invention

The invention relates to a computer-implemented method for co-simulation, using an HIL simulator that runs in real time and an SIL simulator that runs in a simulation time period.

### Description of the Background Art

The company dSPACE offers, under the name “SCALEXIO,” a system for carrying out real-time simulations and implementing hardware-in-the-loop (HIL) test environments, which is provided in particular for developing and validating control devices and systems in the automotive industry. Simulation is an indispensable tool in current product development, in particular in fields with stringent requirements for safety and reliability. Real-time simulations and hardware-in-the-loop tests provide the option for testing the behavior of control devices and systems under realistic conditions without the need for physical prototypes or actual operating conditions. This reduces development times and costs, and at the same time increases product quality and safety.

However, traditional simulation and test environments reach their limits when complex systems and highly dynamic applications are involved. The requirements for flexibility, scalability, and performance are continuously increasing. Therefore, there is an urgent need for more advanced approaches that are capable of efficiently simulating and testing the increasingly complex and interlinked systems. These challenges are addressed by providing an advanced real-time simulation and HIL test system, known as SCALEXIO. SCALEXIO is a modular, scalable system that has been developed by dSPACE in order to meet the demanding requirements of current development and test environments. A flexible platform is provided for the simulation and testing of control devices and systems over a broad spectrum of applications and fields. The core functions include support for complex modeling, real-time simulations, and extensive I/O configurations and user-friendly interfaces for system configuration and monitoring. As a result of its modular architecture, SCALEXIO can be easily adapted to specific requirements and scaled for various simulation scenarios, which makes it a versatile tool in the development and testing landscape.

In addition, dSPACE offers the VEOS platform, which is a comprehensive platform for virtual validation that has been developed specifically for supporting software-in-the-loop (SIL) simulations. These functions allow developers and engineers to perform development and testing of control device software and complex system models in a completely virtual environment. VEOS provides multiple key functions and advantages in the context of SIL simulations.

VEOS allows the creation of virtual ECUs in order to simulate the software of control devices independently of physical hardware. This is particularly useful in the early phases of development, when the actual hardware is possibly not yet available. The platform supports the integration of models that have been created in various modeling languages and tools, such as MATLAB/Simulink, to enable wide-ranging system simulation. This allows seamless simulation of the interplay between control device software and the system model to be controlled. VEOS provides interfaces to tools for automation of tests which allow efficient implementation and management of large quantities of test cases. This helps to improve the software quality and shorten the development time. Extensive diagnostic and visualization tools for VEOS facilitate the identification and analysis of problems in simulated control device software and in the system model.

VEOS also allows the definition and execution of scenarios that emulate actual operating conditions. This helps developers to understand how the software will behave under various conditions. Due to the support of simulations encompassing numerous technical fields (mechanics, electrical systems, hydraulics, for example), VEOS provides a comprehensive view of the system behavior and promotes interdisciplinary cooperation. The modular architecture of VEOS makes it easy to adapt the platform to specific project requirements, and allows scaling to the complexity of the systems being developed. VEOS supports customary industry standards and interfaces, which facilitates integration into existing development processes and the reuse of models and test cases. As a result of these functions, VEOS enables effective, efficient implementation of SIL simulations, resulting in a universal tool in current system and software development, in particular in the automotive field.

In co-simulation, HIL and SIL systems are integrated in such a way that they are able to run simultaneously and synchronously. This means that portions of the system are simulated in real time on physical hardware (HIL), and other portions are simulated in parallel in a virtual environment (SIL). This integration allow comprehensive system testing in which it is possible to assess the interaction between the software and the actual hardware, as well as the interplay of various system components.

The typical approach for co-simulations and the common understanding of co-simulations in the prior art are that a component or a subsystem takes over the timing of the entire simulation system, so that the component or subsystem is generally referred to as a simulation master. The present invention does not deal with this type of co-simulation (also referred to as “strong coupling”), but, rather, concentrates on a simulation system made up of two subsystems which are independent simulators, and instead of incorporating an external simulation master or using one of the simulators as a timing controller, allows both simulators to maintain their timing behavior and to easily exchange data whenever they are available. This co-simulation approach is also referred to as “loose coupling.”

This approach has the advantage that it enhances the simulation performance by decreasing the idle times of both simulator components and reducing the risk of a timeout (task overrun) in the real-time simulator (HIL). However, this has the drawback that the overall system is not deterministic, and temporal inconsistencies may arise in the communication. These inconsistencies may be, for example, drift between the simulator clock pulses, loss of messages, delay in the receipt of messages, or “jitter” in the bus timing interval, to name only a few examples.

Because of these disadvantages, this loose coupling approach is often not considered for co-simulation in current products and technologies, and strong coupling approaches are frequently preferred instead. However, strong coupling may be unsuitable for many simulation systems, in particular for actual examples that are computationally intensive.

Loose coupling generally involves a type of buffering. For an SIL simulation step that lasts longer than with the HIL system in real time, in the SIL system the combination of loose coupling and buffering results in only a minor delay in the message communication, and not in the loss of real-time capability of the HIL simulator. This is known with regard to loose coupling approaches. In the case of bus simulation data exchange, it is also common to exchange bus messages only when they are available.

However, in a loose coupling approach problems may arise with the coupling of the HIL simulator to the SIL simulator. As described above, it is possible that the SIL simulator may temporarily not be running in time with the HIL simulation, since a portion of the simulation steps in the SIL system last longer than the clock pulse duration that is specified by the clock pulse of the co-simulation, and further subsequent steps are then carried out in rapid succession to compensate for this delay. This situation may result in several unintended consequences in the bus timing behavior. In particular, extended delays on the SIL simulator may result in extremely long queues and, when these queues become excessively long, may result in data losses.

A method for synchronizing a simulation with a real-time system is known from DE 10 2017 214 125 A1, which corresponds to US 2020/0257835, and which has the following method steps: A message of the real-time system is awaited, a receive time of the message is measured, at least one further message of the real-time system is awaited, the receive time of the further message is measured, a time difference between the receive times is formed, a deviation of the time difference from a predefined macro increment of the simulation is ascertained, and a start time of the simulation is determined based on the deviation.

WO 2019/219796 A1, which corresponds to US 2021/0081585, which is incorporated herein by reference, describes a method for event-based simulation of a system, wherein the simulation is performed on a computer system comprising a first computing unit and at least one second computing unit, the first computing unit has a simulation time, the second computing unit has an operating system layer and an application layer, the second computing unit has a system time in the operating system layer, at least the second computing unit executes a simulator application, at least one simulation object is executed on the simulation application, the first computing unit manages an event queue, at least one event per simulation step is listed in the event queue, a process to be executed by the simulation object and a simulation time provided for execution of the process are associated with the event, and the second computing unit has a virtual clock generator. The method has the following steps for each simulation step: transmitting, by the first computing unit, a start signal to the virtual clock generator to execute a next simulation step in the second computing unit, and, based on a time difference between a past simulation step and the simulation time period, incrementing the system time of the second computing unit, and executing the upcoming process at the simulation time associated with the process.

### SUMMARY OF THE INVENTION

It is therefore an object of the invention is to avoid disadvantages associated with a co-simulation using an HIL simulator and an SIL simulator with loose coupling, by reducing or completely preventing the occurrence of temporal inconsistencies.

According to the invention, a computer-implemented method for co-simulation using an HIL simulator that runs in real time and an SIL simulator that runs in a simulation time period is thus provided, comprising the following method steps: specifying a periodic clock pulse with clock instants following one another in a constant clock pulse duration; starting an SIL simulation step; creating a message and sending the message from the SIL simulator to the HIL simulator when the SIL simulation step is concluded; receiving the message in a queue of the HIL simulator; reading out from the queue a message at a clock instant by the HIL simulator in each case, and deleting this message in the queue so that a message that is received first from the queue is read out before a later received message and then deleted in the queue; repeating the steps until the co-simulation ends. The first SIL simulation step is started at a first clock instant, and with regard to the subsequent SIL simulation steps, in a case in which the duration of the directly preceding SIL simulation step is the maximum clock pulse duration, the directly following SIL simulation step is started at the next possible clock instant in each case, and otherwise the directly following SIL simulation step is immediately started after conclusion of the previous SIL simulation step.

It is thus an important aspect of the invention that within the scope of the co-simulation involving the parallel use of a hardware-in-the-loop (HIL) simulator that operates in real time, and a software-in-the-loop (SIL) simulator that runs in a simulation time period that is independent from the actual time or real time, after conclusion of each SIL simulation step a message is sent from the SIL simulator to the HIL simulator, this message being received in a queue of the HIL simulator and then being read at a specified clock instant and subsequently being removed from the queue. The processing sequence is designed in such a way that messages received earlier are processed and deleted before later arriving messages (first in first out (FIFO) principle). A periodic clock pulse made up of successive clock instants having a constant duration is thus specified.

The method steps are repeated until the co-simulation ends, typically after a predefined number of steps are executed or when a certain event has been achieved. A distinction is made with regard to the start of successive SIL simulation steps: If the duration of the previous step corresponded to the maximum clock pulse duration, the next step is started at the next possible clock instant. However, if the previous step lasted longer, the next step starts directly after the previous step ends in order to keep the lag of the SIL simulator as small as possible.

As a result of sending, after each individual SIL step, a message that is stored in the queue, the SIL simulator may lag behind the HIL simulator if an SIL step has lasted for a correspondingly longer time. However, due to the buffering of the messages in the queue, the messages arrive in the HIL simulator at defined points in time, so that correct association and thus error-free use of the messages in the HIL simulator are made possible.

The messages created by the SIL simulator may have different contents. According to one preferred refinement of the invention, however, upon creation of a message a piece of simulation metadata characterizing at least one property of the co-simulation is included in each case into the message. This piece of simulation metadata preferably contains the present state of the queue, the simulated time, and/or the actual time that is present in the SIL simulator or in the HIL simulator. Since according to this preferred embodiment of the invention, each message contains such a piece of simulation metadata and each of these messages is sent after conclusion of an SIL step, these types of messages are also referred to as heartbeat messages.

The messages may also have other contents in addition to such simulation metadata. In particular, according to one preferred refinement of the invention it is provided that bus data are exchanged between the SIL simulator and the HIL simulator. In particular, a piece of bus data characterizing at least one property of a bus of the SIL simulator is preferably included into precisely every nth message, where n is a constant integer greater than 1. The bus of the SIL simulator, for which a piece of bus data characterizing the SIL simulator is included into the message, is preferably a virtual bus. It is thus possible, for example, that after each SIL step a heartbeat message is sent, and after every fifth step this heartbeat message is supplemented by a piece of bus data, resulting in a bus message. Due to the buffering in the queue that is read out in the specified clock pulse, even when the SIL simulator lags, every fifth clock pulse the HIL simulator obtains a piece of bus data, which may then be appropriately associated and further processed in the HIL simulator.

According to an example, in a case in which the queue contains more than a predetermined number of messages, the method is supplemented in such a way that after the message is read out and deleted, the subsequent message in the queue is deleted without being read out if it is not a message into which a piece of bus data has been included. In this regard, in a case in which the message has not been deleted without being read out because it is a message into which a piece of bus data has been included, after the message into which a piece of bus data has been included is read out and deleted, the subsequent message in the queue is preferably deleted without being read out. This procedure allows lagging of the SIL simulator behind the HIL simulator to be held within limits, but with the consequence that at least for two successive messages having a piece of bus data, the predefined clock pulse interval is decreased by one clock pulse: If the messages having a piece of bus data were previously sent in such a way that every fifth message indicated a piece of bus data, in the present case it is the fourth message which for one time contains a piece of bus data.

The physical coupling of the SIL simulator to the HIL simulator for sending messages may take place in different ways. According to one preferred refinement of the invention, however, the message is sent from the SIL simulator to the HIL simulator via Ethernet, preferably via standard Ethernet.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF DRAWINGS

The present invention will become more fully understood from the detailed description given hereinbelow and the accompanying drawings which are given by way of illustration only, and thus, are not limitive of the present invention, and wherein:

FIG. 1 schematically shows an example of a strong coupling approach, known from the prior art, between an SIL simulator and an HIL simulator in which the HIL simulator is the simulation master,

FIG. 2 schematically shows a loose coupling communication with buffering from the priori art,

FIG. 3 schematically shows a comparison between the time bases in the SIL simulator and in the HIL simulator from the prior art,

FIG. 4 schematically shows a situation in which, regardless of the presence of buffers on the receiver side, the bus timing is still inconsistent during the exchange of data between the SIL simulator and the HIL simulator from the prior art,

FIG. 5 shows a simplified illustration of the situation from FIG. 4,

FIG. 6 schematically shows a method according to an example of the invention,

FIG. 7 schematically shows further steps of the method from FIG. 6, and

FIG. 8 schematically shows a method according to an example of the invention.

### DETAILED DESCRIPTION

As described at the outset, the present invention relates to co-simulation using an SIL simulator and an HIL simulator. A conventional approach for the co-simulation and the associated understanding of co-simulation are that a component or a subsystem takes over the timing of the entire simulation system, so that this component or this subsystem may be referred to as a simulation master.

The present invention deals with this type of co-simulation, sometimes also referred to as strong coupling; however, in the present case a simulation system is involved which has two subsystems, namely, an SIL simulator and an HIL simulator, each being independent simulators, and instead of incorporating an external simulation master or using one of the two simulators as a timing controller, both simulators are allowed to maintain their timing behavior and to exchange data whenever they are available. This co-simulation approach is also referred to as loose coupling.

This loose coupling approach has the advantage that it enhances the simulation performance by decreasing the idle times of both simulator components and reducing the risk of a timeout (task overrun) in the HIL simulator. However, this has the drawback that the overall system is not automatically deterministic, and temporal inconsistencies may arise in the communication. Because of these disadvantages, the loose coupling approach is often not considered for this type of co-simulation, and strong coupling approaches are preferred instead. However, strong coupling may be unsuitable for many simulation systems, in particular for very computationally intensive tasks.

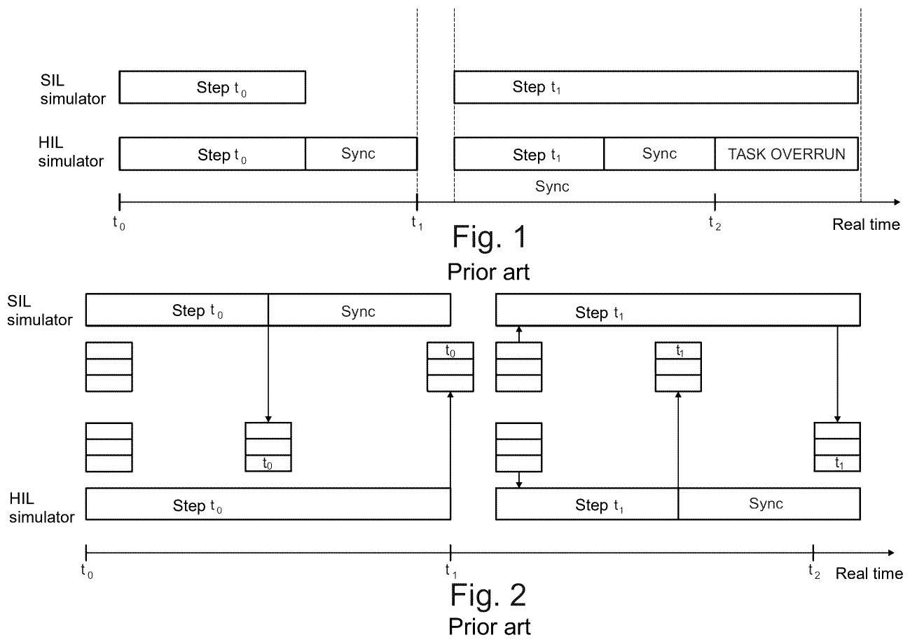

FIG. 1 shows an example of a strong coupling approach between an SIL simulator and an HIL simulator, in which the HIL simulator is the simulation master. In this example, in step t₁ the SIL simulator requires longer than one clock pulse duration to carry out this step, which in real time takes less than one clock pulse duration, resulting in a task overrun in the HIL simulator, causing the latter to lose the real time synchronization. Such a phenomenon occurs regardless of which component is the simulation master, when the SIL simulator is not able to maintain real-time capability, even if this happens only temporarily. This short-term loss of real-time capability is practically unavoidable in SIL systems, for example when computationally intensive steps occur or steps are interrupted by operating system or system calls.

The present case involves a loose coupling approach in which the objective is to reduce the disadvantages of loose coupling by decreasing or avoiding the occurrence of temporal inconsistencies. Loose coupling communication generally involves buffering, as illustrated in FIG. 2. In this case, a simulation step that lasts longer than in real time results in only a minor delay in the message communication in the SIL simulator, and not in the loss of real-time capability of the HIL simulator. This is the typical prior art when loose coupling approaches are involved. In the case of bus simulation data exchange, it is also common to exchange bus messages just when they are available. However, within the scope of a loose coupling approach, with the coupling of an SIL simulator to an HIL simulator it may be problematic that the SIL simulator temporarily loses the synchronization with the real-time system when a simulation step lasts longer than the specified clock pulse duration, and further steps are carried out in rapid succession to compensate for this delay. Such behavior is illustrated in FIG. 3.

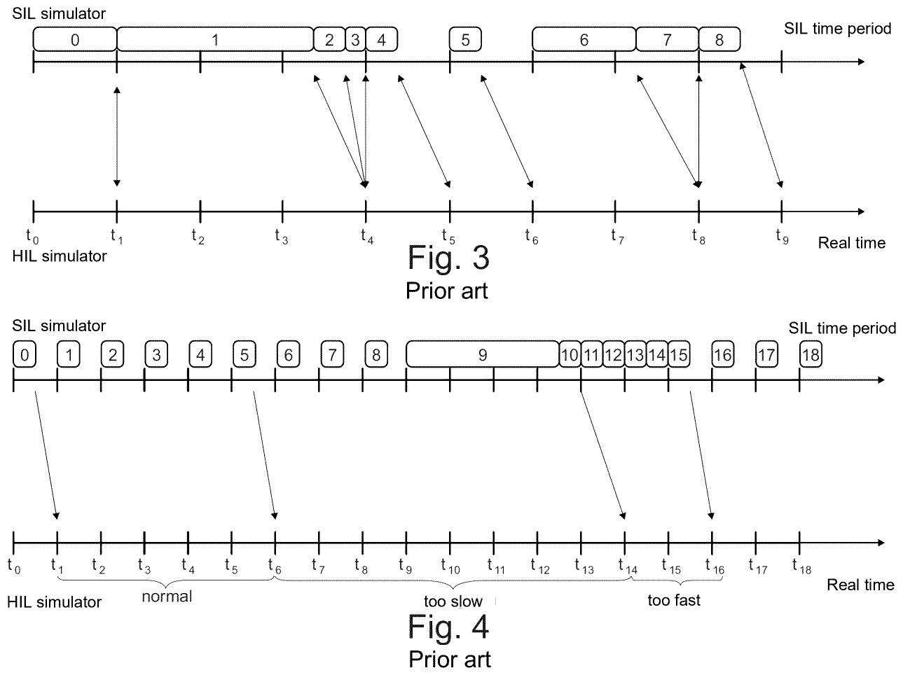

FIG. 3 shows a comparison between the time bases in the SIL simulator and in the HIL simulator. The SIL simulator is configured in such a way that it maintains real time, viewed over its entire runtime. This means that in the case of a simulation step lasting longer than a real-time clock pulse duration, the simulator attempts to make up for the associated lag in order to once again achieve synchronization between the actual and the simulated time. In loose coupling approaches and for the case that only bus messages are exchanged, this behavior may result in undesirable consequences in the bus timing behavior, even in the case of buffered communication presented here. This is schematically illustrated in FIG. 4.

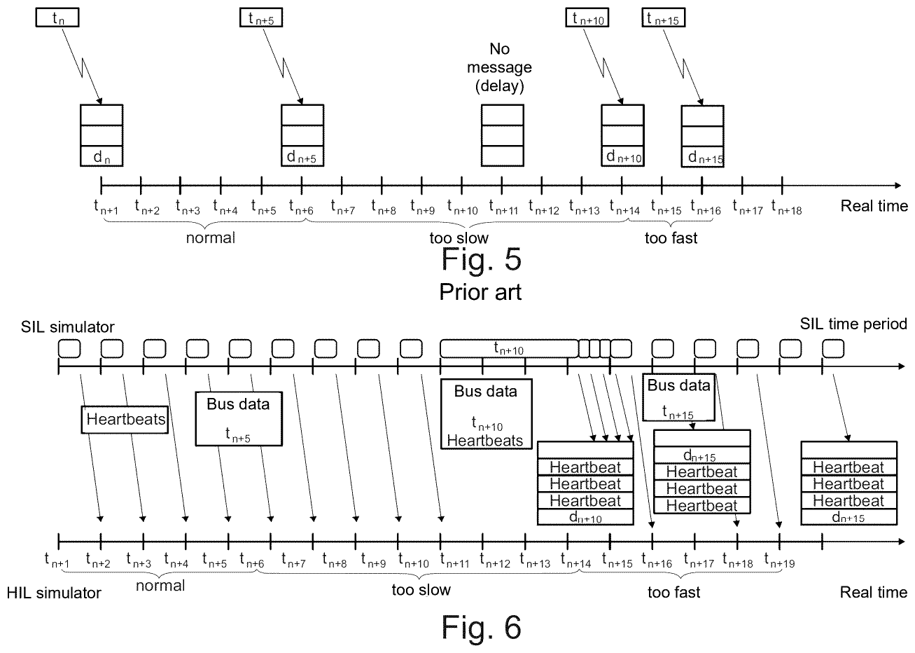

It is apparent from FIG. 4 that, regardless of the presence of buffers on the receiver side, the bus timing is still inconsistent during the exchange of data between the real-time and the nonreal-time systems. In the following discussion, simplified illustrations are sometimes used by showing only the receiver side of the HIL system. The behavior illustrated in FIG. 4 is then represented as shown in FIG. 5. FIG. 5 shows the HIL side of the data exchange within the scope of the simulation: Due to a momentary loss of real-time capability on the SIL side, bus data that are to be read every 5 simulation steps instead arrive at essentially random intervals. Since these data are immediately interpreted and transferred onto the bus, this results in intervals with a random duration between the bus messages. These random interval durations may result in bus collisions and errors in connected control devices on the HIL side. Extended delays on the SIL simulator may thus lead to extremely long queues, and possibly data losses. The invention addresses this problem as follows:

Once again two communication components are provided, namely, an HIL simulator that runs in real time and an SIL simulator that runs in a simulation time period, in particular using a loose coupling approach. These simulators exchange simulation metadata and also bus data via Ethernet according to the following method:

A periodic clock pulse with clock instants following one another in a constant clock pulse duration is specified. A first SIL simulation step is started at the clock instant zero. When the SIL simulation step is concluded, a message is created and sent from the SIL simulator to the HIL simulator. The message is received in a FIFO queue of the HIL simulator. At each clock instant a message is read out from the queue by the HIL simulator in each case and is subsequently deleted in the queue. This process is repeated until the end of the co-simulation is reached.

It is important that after the start of the first SIL simulation step at a clock instant zero, with regard to the subsequent SIL simulation steps, in a case in which the duration of the directly preceding SIL simulation step is the maximum clock pulse duration, the directly following SIL simulation step is started at the next possible clock instant in each case, and otherwise the directly following SIL simulation step is immediately started after conclusion of the previous SIL simulation step, as illustrated in FIG. 3 regarding steps 2 and 3, for example. Upon creation of the messages, simulation metadata involving the present state of the queue, the simulated time, and/or the actual time that is present in the SIL simulator or in the HIL simulator are included each time into the message. These messages are referred to as heartbeat messages. In addition, bus data characterizing the properties of a bus of the SIL simulator are included into precisely every fifth message. These messages are also referred to as bus messages. This design allows problems in bus timing to be avoided when messages arrive at too small intervals, as schematically illustrated in FIG. 6.

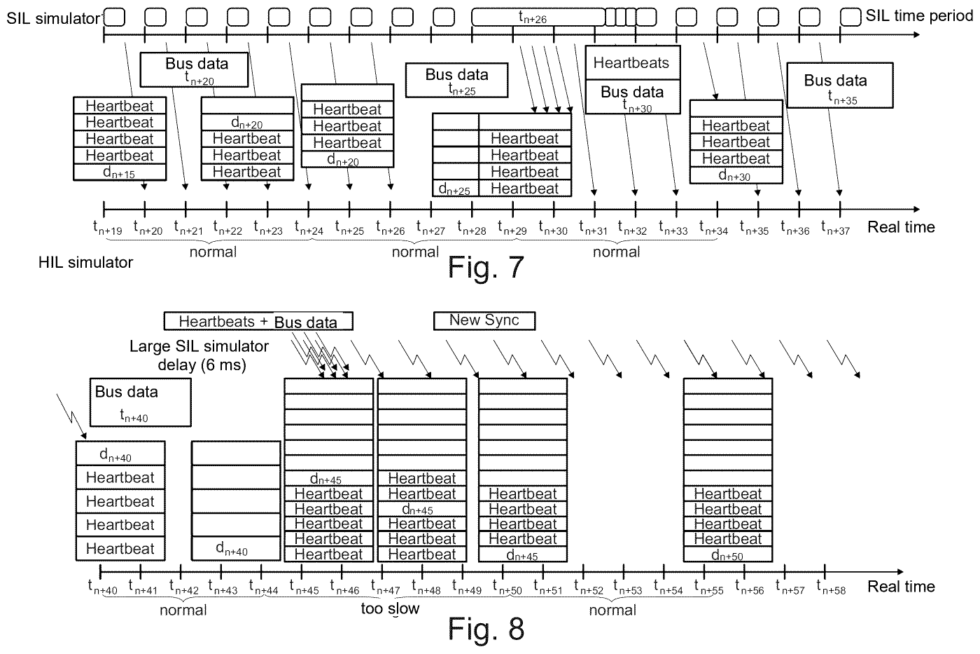

Since in each simulation step exactly one message is output, regardless of whether or not it contains bus data, situations are avoided in which bus messages containing bus data are read out from the queue by the HIL simulator at too small intervals due to previous loss of the real-time capability of the SIL simulator. In addition, this approach allows a certain buffering of heartbeat messages and bus messages to be maintained when such a deviation from real-time behavior occurs. This has the effect that the system is protected from further synchronization losses of the same order of magnitude, with the secondary effect that the time delay between the two simulators increases, i.e., the SIL simulator does not lag farther behind the HIL simulator. One example is schematically illustrated in FIG. 7. FIG. 7 shows the continuation of the example from FIG. 6 from time tₙ₊₁₉. In this case the backlog of three messages, resulting from delayed sending of three messages, protects the system from further delays by three messages.

Furthermore, according to an example of the invention, a method for resynchronization is provided, as schematically illustrated in FIG. 8. This mechanism allows a heartbeat message to be ignored, in particular by shifting the FIFO queue by two steps and thus eliminating a heartbeat message when the synchronization between the components is severely impaired. In the case illustrated in FIG. 8, a particularly long delay of simulation steps has resulted in a subsequent queue containing six messages on the HIL side. To avoid a correspondingly long delay between the simulators, one heartbeat message has been discarded from the queue. In this way, the system can return to an acceptable queue status within a certain time frame in the event of a particularly long SIL computation step.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for co-simulation, using an HIL simulator that runs in real time and an SIL simulator that runs in a simulation time, the method comprising:
specifying a periodic clock pulse with clock instants following one another in a constant clock pulse duration;
a) starting an SIL simulation step;
b) creating a message and sending the message from the SIL simulator to the HIL simulator when the SIL simulation step is concluded;
c) receiving the message in a queue of the HIL simulator;
d) reading out from the queue a message at a clock instant by the HIL simulator in each case, and deleting this message in the queue so that a message that is received first from the queue is read out before a later received message and then deleted in the queue; and
e) repeating the steps a) through d) until the co-simulation ends,
wherein the first SIL simulation step is started at a first clock instant, and
wherein, with respect to the subsequent SIL simulation steps, in a case in which the duration of the directly preceding SIL simulation step is a maximum clock pulse duration, the directly following SIL simulation step is started at a next possible clock instant or otherwise the directly following SIL simulation step is immediately started after conclusion of the previous SIL simulation step.

2. The computer-implemented method according to claim 1, wherein upon creation of a message a piece of simulation metadata characterizing at least one property of the co-simulation is included in each case into the message.

3. The computer-implemented method according to claim 2, wherein the piece of simulation metadata is selected from the following data:
the present state of the queue;
the simulated time; and/or
the actual time that is present in the SIL simulator or in the HIL simulator.

4. The computer-implemented method according to claim 1, wherein a piece of bus data describing at least one property of a bus of the SIL simulator is included into precisely every n^{th} message, where n is a constant integer greater than 1.

5. The computer-implemented method according to claim 4, wherein, when the queue contains more than a predetermined number of messages, step d) is supplemented such that after the message is read out and deleted, the subsequent message in the queue is deleted without being read out if it is not a message into which a piece of bus data has been included.

6. The computer-implemented method according to claim 5, wherein, when the message has not been deleted without being read out because it is a message into which a piece of bus data has been included, in subsequent step d), after the message into which a piece of bus data has been included is read out and deleted, the subsequent message in the queue is deleted without being read out.

7. The computer-implemented method according to claim 1, wherein the message is sent from the SIL simulator to the HIL simulator via Ethernet.
